(19) United States
(12) Patent Application Publication
(10) Pub. No.: US 2024/0413046 A1
(43) Pub. Date: Dec. 12, 2024

(54) SEMICONDUCTOR MODULE, POWER ELECTRONIC SUBSTRATE AND METHOD FOR FABRICATING A SEMICONDUCTOR MODULE

(71) Applicant: Infineon Technologies AG, Neubiberg (DE)

(72) Inventors: Frank Sauerland, Werne (DE); Roland Speckels, Kamen (DE); Markus Fink, Zell (DE)

(21) Appl. No.: 18/732,818

(22) Filed: Jun. 4, 2024

(30) Foreign Application Priority Data
Jun. 6, 2023 (DE) 102023205266.0

(51) Int. Cl. H01L 23/373; H01L 21/48; H01L 21/56; H01L 23/31

(52) U.S. Cl. CPC H01L 23/3735; H01L 21/4807; H01L 21/565; H01L 23/3121

(57) ABSTRACT

A semiconductor module includes: a power electronic substrate having a first conductive layer, a second conductive layer, and an insulating layer separating the first and second conductive layers; at least one semiconductor die arranged over the first conductive layer; and a molded body having a first side and an opposite second side. The molded body encapsulates the semiconductor die and partially encapsulates the power electronic substrate such that the second conductive layer is at least partially exposed from the second side of the molded body. The insulating layer protrudes beyond a contour of the first conductive layer and/or beyond a contour of the second conductive layer at lateral sides of the power electronic substrate by a nonzero protrusion. A ratio of a thickness of the insulating layer to a length of the protrusion is 0.8 or more.

### TECHNICAL FIELD

This disclosure relates in general to a semiconductor module, in particular a semiconductor module comprising a power electronic substrate, as well as to a power electronic substrate and to a method for fabricating a semiconductor module.

### BACKGROUND

A semiconductor module may comprise a power electronic substrate, for example a substrate of the type DCB, a semiconductor die arranged on the power electronic substrate and a molded body encapsulating the semiconductor die. The power electronic substrate and the molded body may exhibit a significant difference in their coefficients of thermal expansion. Therefore, a sufficient change in temperature, e.g. during or after soldering or sintering the semiconductor module to a heatsink, may cause significantly different amounts of thermal expansion or shrinkage of the power electronic substrate respectively the molded body. This in turn may cause a significant bend and even cracks in the power electronic substrate, thereby affecting electrical insulation properties of the power electronic substrate.

Improved semiconductor modules, improved power electronic substrates for semiconductor modules and improved methods for fabricating a power electronic substrate may help in solving these and other problems.

### SUMMARY

Various aspects pertain to a semiconductor module, comprising: a power electronic substrate comprising a first conductive layer, a second conductive layer and an insulating layer separating the first and second conductive layers; at least one semiconductor die arranged over the first conductive layer; and a molded body comprising a first side and an opposite second side, the molded body encapsulating the semiconductor die and partially encapsulating the power electronic substrate such that the second conductive layer is at least partially exposed from the second side of the molded body, wherein the insulating layer protrudes beyond a contour of the first conductive layer and/or beyond a contour of the second conductive layer at lateral sides of the power electronic substrate by a nonzero protrusion, and wherein a ratio of a thickness of the insulating layer to a length of the protrusion is 0.8 or more.

Various aspects pertain to a power electronic substrate configured for use in a semiconductor module, the power electronic substrate comprising: a first conductive layer, a second conductive layer and an insulating layer separating the first and second conductive layers, wherein the insulating layer protrudes beyond a contour of the first conductive layer and/or beyond a contour of the second conductive layer at lateral sides of the power electronic substrate by a nonzero protrusion, and wherein a ratio of a thickness of the insulating layer to a length of the protrusion is 0.8 or more.

Various aspects pertain to a method for fabricating a semiconductor module, the method comprising: providing a power electronic substrate comprising a first conductive layer, a second conductive layer and an insulating layer separating the first and second conductive layers; arranging at least one semiconductor die over the first conductive layer; and encapsulating the semiconductor die and partially encapsulating the power electronic substrate with a molded body comprising a first side and an opposite second side, such that the second conductive layer is at least partially exposed from the second side of the molded body, wherein the insulating layer protrudes beyond a contour of the first conductive layer and/or beyond a contour of the second conductive layer at lateral sides of the power electronic substrates by a nonzero protrusion, and wherein a ratio of a thickness of the insulating layer to a length of the protrusion is 0.8 or more.

### BRIEF DESCRIPTION OF THE DRAWINGS

The accompanying drawings illustrate examples and together with the description serve to explain principles of the disclosure. Other examples and many of the intended advantages of the disclosure will be readily appreciated in view of the following detailed description. The elements of the drawings are not necessarily to scale relative to each other. Identical reference numerals designate corresponding similar parts.

FIG. 1 shows a sectional view of a semiconductor module comprising a power electronic substrate, wherein a ratio of a thickness of an insulating layer of the substrate to a length of a protrusion of the insulating layer with respect to a conductive layer of the substrate is 0.8 or more.

FIG. 2 shows a sectional view of a further semiconductor module, wherein the contours of both conductive layers of the power electronic substrate are congruent.

FIG. 3 shows a sectional view of a detail of a further semiconductor module, wherein end faces of the conductive layers of the power electronic substrate are essentially perpendicular to the upper and lower sides of the insulating layer.

FIG. 4 shows a sectional view of a detail of a further semiconductor module, wherein the end faces of the conductive layers of the power electronic substrate are tapered.

FIG. 5 shows an electronic system comprising a semiconductor module coupled to a heatsink.

FIG. 6 shows a sectional view of a power electronic substrate configured for use in a semiconductor module.

FIG. 7 is a flow chart of an exemplary method for fabricating a semiconductor module.

### DETAILED DESCRIPTION

In the following detailed description, known structures and elements are shown in schematic form in order to facilitate describing one or more aspects of the disclosure. In this regard, directional terminology, such as “top”, “bottom”, “left”, “right”, “upper”, “lower” etc., is used with reference to the orientation of the Figure(s) being described. Because components of the disclosure can be positioned in a number of different orientations, the directional terminology is used for purposes of illustration only. It is to be understood that other examples may be utilized and structural or logical changes may be made.

In addition, while a particular feature or aspect of an example may be disclosed with respect to only one of several implementations, such feature or aspect may be combined with one or more other features or aspects of the other implementations as may be desired and advantageous for any given or particular application, unless specifically noted otherwise or unless technically restricted. Furthermore, to the extent that the terms “include”, “have”, “with” or other variants thereof are used in either the detailed description or the claims, such terms are intended to be inclusive in a manner similar to the term “comprise”. The terms “coupled” and “connected”, along with derivatives thereof may be used. It should be understood that these terms may be used to indicate that two elements cooperate or interact with each other regardless of whether they are in direct physical or electrical contact, or they are not in direct contact with each other; intervening elements or layers may be provided between the “bonded”, “attached”, or “connected” elements. However, it is also possible that the “bonded”, “attached”, or “connected” elements are in direct contact with each other. Also, the term “exemplary” is merely meant as an example, rather than the best or optimal.

The examples of a semiconductor module described below may use various types of semiconductor dies or circuits incorporated in the semiconductor dies, among them AC/DC or DC/DC converter circuits, inverter circuits, power MOSFET transistors, power Schottky diodes, JFETs (Junction Gate Field Effect Transistors), power bipolar transistors, power integrated circuits, etc.

An efficient semiconductor module, an efficient power electronic substrate for a semiconductor module and an efficient method for fabricating a semiconductor module may for example reduce material consumption, ohmic losses, chemical waste, etc. and may thus enable energy and/or resource savings. Improved semiconductor modules, improved power electronic substrates for a semiconductor module and improved methods for fabricating a semiconductor module, as specified in this description, may thus at least indirectly contribute to green technology solutions, i.e. climate-friendly solutions providing a mitigation of energy and/or resource use.

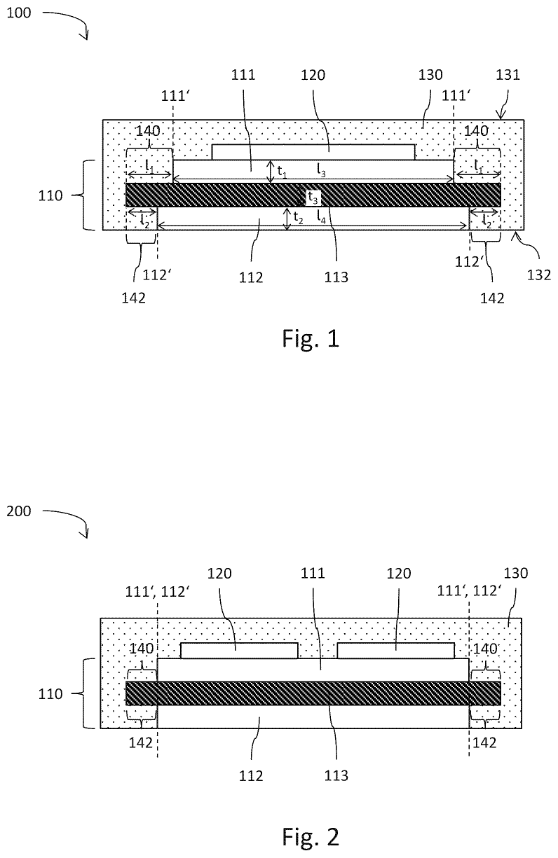

FIG. 1 shows a sectional view of a semiconductor module 100 comprising a power electronic substrate 110, at least one semiconductor die 120 and a molded body 130.

The semiconductor module 100 may for example be a power semiconductor module configured to operate with a high voltage and/or a strong electrical current. The semiconductor module 100 may comprise any suitable electrical circuitry, for example a half bridge circuit, a full bridge circuit, a converter circuit, an inverter circuit, etc.

The power electronic substrate 110 comprises a first conductive layer 111, a second conductive layer 112 and an insulating layer 113 separating the first and second conductive layers 111, 112. The insulating layer 113 may be configured to electrically insulate the first and second conductive layers 111, 112. The power electronic substrate 110 may for example be a direct copper bonded (DCB) substrate, a direct aluminum bonded (DAB) substrate, or an active metal brazed (AMB) substrate.

The first and second conductive layers 111, 112 may comprise or consist of any suitable metal or metal alloy. For example, the first and second conductive layers 111, 112 may comprise or consist of Al or Cu. The first and second conductive layers 111, 112 may have identical materials or material compositions or different materials or material compositions. The insulating layer 113 may comprise or consist of any suitable dielectric material. For example, the insulating layer 113 may comprise or consist of a suitable ceramic, e.g. Al₂O₃, Si₃N₄ or AlN. The insulating layer 113 may be comparatively brittle.

The first and second conductive layers 111, 112 and the insulating layer 113 may have any suitable thickness. For example, the first conductive layer 111 may have a thickness t₁ in the range of about 100 μm to about 1 mm. The thickness t₁ may also be about 200 μm, about 300 μm, about 320 μm, about 500 μm, or about 700 μm. The second conductive layer 112 may have a thickness the which may be in the same range as described with respect to the thickness t₁. The thicknesses t₁ and the may be identical or different from each other. The insulating layer 113 may have a thickness t₃ in the range of about 150 μm to 800 μm. The thickness t₃ may also be about 200 μm, about 300 μm, about 380 μm, about 500 μm, or about 600 μm.

According to an example, the first conductive layer 111 is a structured layer comprising, e.g., conductive pads and/or conductive tracks and the second conductive layer 112 is a non-structured layer. According to another example, both the first and the second conductive layer 111, 112 are structured layers or non-structured layers.

The semiconductor die 120 is arranged over the first conductive layer 111. The semiconductor die 120 may be electrically connected to the first conductive layer 111. For example, the semiconductor die 120 may comprise a first power terminal (e.g. a drain terminal) arranged on the lower main side of the semiconductor die 120, wherein the first power terminal is coupled to the first conductive layer 111 by a joint like a solder joint, a sintered joint or a joint comprising conductive glue. The semiconductor die 120 may for example also comprise a second power terminal arranged on the upper main side of the semiconductor die 120. The second power terminal may be coupled to the first conductive layer 111 or to another component of the semiconductor module 100 by an electrical connector like one or more bond wires, a ribbon or a contact clip. The semiconductor die 120 may for example also comprise a control terminal, e.g. a gate terminal, arranged on the upper main side.

The semiconductor module 100 may also comprise external contacts, e.g. power contacts and a control contact, which may for example be arranged at one or more lateral sides of the molded body 130. The power contacts may be connected to the power terminals of the semiconductor die 120 and the control contact may be connected to the control terminal of the semiconductor die 120.

According to an example, the semiconductor module 100 comprises a plurality of semiconductor dies 120. The semiconductor dies 120 may all be of the same type or the semiconductor dies 120 may be different types of dies. The semiconductor dies 120 may all be arranged over the same power electronic substrate 110 or the semiconductor module 100 may comprise a plurality of power semiconductor substrates 110, wherein some or all of the semiconductor dies 120 are arranged over different ones of the power electronic substrates 110.

The molded body 130 comprises a first side 131 and an opposite second side 132. The molded body 130 encapsulates the semiconductor die 120. Furthermore, the molded body 130 partially encapsulates the power electronic substrate 110 such that the second conductive layer 112 is at least partially exposed from the second side 132 of the molded body 130. For example, the molded body 130 may essentially encapsulate the power electronic substrate 110 on all sides except for the lower main side of the second conductive layer 112.

As shown in FIG. 1, the insulating layer 113 protrudes beyond a contour 111′ of the first conductive layer 111 at lateral sides of the power electronic substrate 110 by a nonzero protrusion 140. The power electronic substrate 110 may have the protrusion 140 on all lateral sides or on only three lateral sides or on only two lateral sides or on a single lateral side. In the case that the power electronic substrate 110 has the protrusion 140 on more than one lateral side, the individual protrusions 140 may have identical dimensions or different dimensions.

The protrusion 140 may for example have a length l₁ in the range of about 0.1 mm to about 0.7 mm. The lower limit of this range may also be about 0.2 mm, about 0.3 mm, about 0.35 mm, or about 0.4 mm and the upper limit may also be about 0.6 mm or about 0.5 mm.

According to an example, a ratio of the thickness t₃ of the insulating layer 113 to the length l₁ of the protrusion 140 is 0.8 or more, or 0.9 or more, or 0.91 or more, or 1.0 or more, or 1.1 or more, or 1.2 or more, or 1.5 or more.

Additionally or alternatively to the protrusion 140, the insulating layer 113 may protrude beyond a contour 112′ of the second conductive layer 112 by a nonzero further protrusion 142. The further protrusion 142 may have a length l₂ which may for example have a value in the range disclosed with respect to the length l₁.

According to an example, the length l₂ is equal to the length l₁ and according to another example, the lengths l₁ and l₂ are different. In other words, the first conductive layer 111 may have a first edge length l₃ and the second conductive layer 112 may have a second edge length l₄, wherein the edge lengths l₃ and l₄ may be identical or different. In the example shown in FIG. 1, the first edge length l₃ is smaller than the second edge length l₄. For example, the first edge length l₃ is at least 0.3 mm smaller than the second edge length 14.

However, it is also possible that the insulating layer 113 protrudes beyond the contour 112′ of the second conductive layer 112 but does not protrude beyond the contour 111′ of the first conductive layer 111 or that the insulating layer 113 protrudes beyond the contour 111′ of the first conductive layer 111 but does not protrude beyond the contour 112′ of the second conductive layer 112. In other words, the contour of the insulating layer 113 may be congruent with one of the contours 111′ and 112′ in the case that these contours are different.

Furthermore, a ratio of the thickness ty of the insulating layer 113 to the length l₂ of the further protrusion 142 may be 0.8 or more, or 0.9 or more, or 0.91 or more, or 1.0 or more, or 1.1 or more, or 1.2 or more, or 1.5 or more. The ratio of the thickness t₃ to the length l₁ and the ratio of the thickness t₃ to the length l₂ may be identical or different.

The individual components of the semiconductor module 100, for example the power electronic substrate 110 on the one hand and the molded body 130 on the other hand, may have different coefficients of thermal expansion. This difference may be comparatively large and could potentially cause the power electronic substrate 110 to exhibit a significant bend after a temperature change (such a temperature change may for example occur when the semiconductor module 100 is soldered or sintered to e.g. a heatsink and subsequently cools down). In the case that the bend exceeds a critical threshold, the power electronic substrate 110, in particular the insulating layer 113, may take damage. For example, the insulating layer 113 may crack. Such a crack may negatively impact the electrical insulation between the conductive layers 111, 112.

The problem of such cracks may predominantly occur at the edge of the insulating layer 113 since the bending stress is at its highest there. However, the comparatively large ratio of the thickness of the insulating layer 113 to the length of the protrusion 140 or 142 may reduce or at least homogenize the bending stress at the edge of the insulating layer 113 and may thereby reduce or eliminate the occurrence of such cracks in the insulating layer 113. The bending stress may also be reduced or at least homogenized in the case that the protrusion 140 has a shorter length than the further protrusion 142, as shown in the example of FIG. 1.

FIG. 2 shows a sectional view of a further semiconductor module 200 which may be similar or identical to the semiconductor module 100, except for the differences described in the following.

In particular, in the semiconductor module 200 the insulating layer 113 protrudes beyond the contours of the first and second conductive layers 111, 112 by protrusions 140, 142 of identical length. In other words, the contour 111′ of the first conductive layer 111 and the contour 112′ of the second conductive layer 112 are congruent (the conductive layers 111, 112 have identical edge lengths).

In the example shown in FIG. 2, the semiconductor module 200 comprises at least two semiconductor dies 120 arranged over a common power electronic substrate 110. The semiconductor dies 120 may for example be electrically connected via the first conductive layer 111. It is of course also possible that only a single semiconductor die 120 is arranged over the power electronic substrate 110.

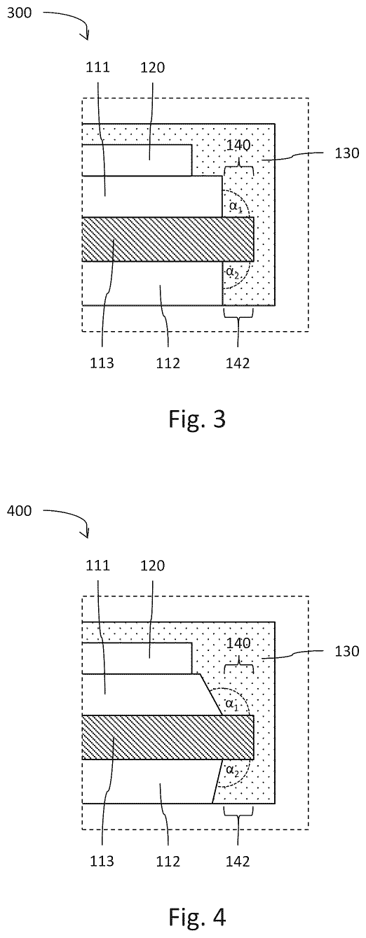

FIG. 3 shows a sectional view of a detail of a further semiconductor module 300 which may be similar or identical to the semiconductor module 100 or 200. The semiconductor module 300 may comprise all components described with respect to the semiconductor module 100 or 200.

As shown in the detail view of FIG. 3, a lateral end face of the first conductive layer 111 is arranged at an angle di with respect to an upper side of the insulating layer 113. Conversely, a lateral end face of the second conductive layer 112 is arranged at an angle: with respect to a lower side of the insulating layer 113. The angles a₁ and a₂ may be identical, as shown in the example of FIG. 3. However, it is also possible that the angles a₁ and a₂ are different. According to the example shown in FIG. 3, the angles a₁ and a₂ are essentially 90°.

The first conductive layer 111 may have the same angle di at all of the lateral sides, or at only one of the lateral sides, at two of the lateral sides (e.g. at two opposite lateral sides), or at three of the lateral sides. Conversely, the second conductive layer 112 may have the same angle a₂ at all of the lateral sides, or at only one of the lateral sides, at two of the lateral sides (e.g. at two opposite lateral sides), or at three of the lateral sides.

FIG. 4 shows a detail of a further semiconductor module 400 which may be similar or identical to the semiconductor module 300, except for the differences described in the following.

In particular, in the semiconductor module 400, the first conductive layer 111 and/or the second conductive layer comprises a taper at the lateral sides of the power electronic substrate. That is, in the semiconductor module 400 the angle a₁ has a value of more than 90°, for example a value of 120° or a value of 135° or more. In other words, with respect to a plane which is perpendicular to the first and/or second conductive layer 111, 112, the lateral end faces of the first conductive layer 111 may have a non-zero taper (e.g. a taper of 30° or more, or a taper of 45° or more).

The second conductive layer 112 may have an angle a₂ which may for example be in the same range as disclosed with respect to the first conductive layer 111. However, it is for example also possible that the second conductive layer 112 is not tapered.

The tapered end faces of the first conductive layer 111 and/or the second conductive layer 112 may reduce the bending stress in the insulating layer 113, similar to how the comparatively large ratio between the thickness of the insulating layer 13 and the length of the protrusion reduces the bending stress.

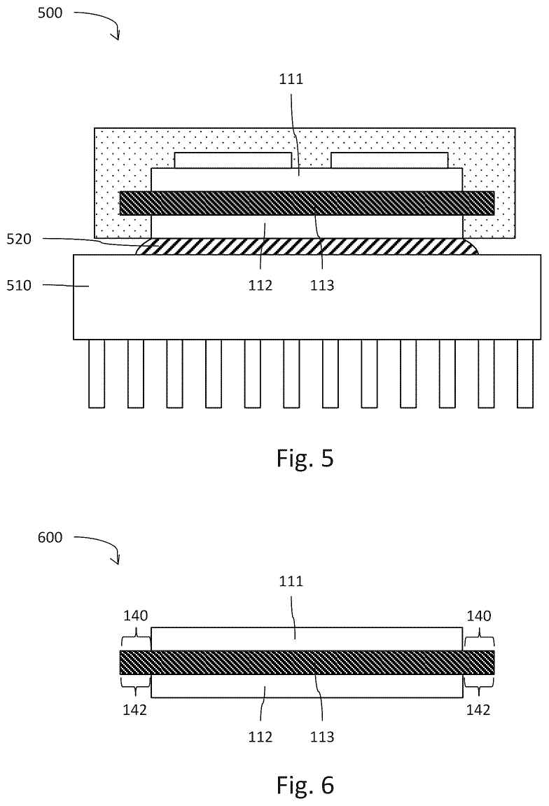

FIG. 5 shows a sectional view of an electronic system 500 comprising the semiconductor module 200 and a heatsink 510. Instead of the semiconductor module 200, the electronic system 500 may of course also comprise the semiconductor module 100, 300 or 400.

Furthermore, the electronic system 500 may comprise more than one semiconductor module, e.g. two, three, four, etc. semiconductor modules which may for example all be arranged side-by-side on the heatsink 510.

According to an example, the semiconductor module 200 may be coupled to the heatsink 510 via an attachment layer 520 which may for example comprise or consist of a suitable solder material or a suitable sintered material. In other words, the semiconductor module 200 may e.g. be soldered or sintered to the heatsink 510.

The comparatively high ratio of the thickness of the insulating layer 113 to the length of the protrusion 140 and/or the tapered end faces may for example help in reducing a bend in the power electronic substrate 110. Such a bend may for example occur after soldering or sintering the semiconductor module 200 to the heatsink 510.

FIG. 6 shows a sectional view of a power electronic substrate 600 configured for use in a semiconductor module like the semiconductor modules 100-400.

The power electronic substrate 600 may essentially be similar or identical to the power electronic substrate 110. The power electronic substrate 600 in particular comprises the protrusion 140 and/or the tapered end faces as described further above.

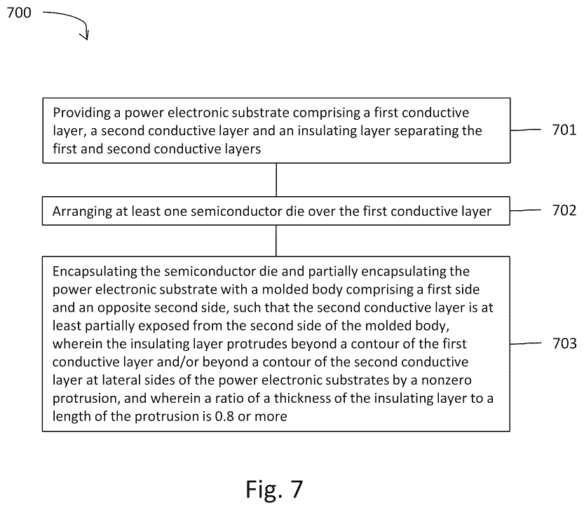

FIG. 7 is a flow chart of a method 700 for fabricating a semiconductor module. The method 700 may for example be used to fabricate anyone of the semiconductor modules 100 to 400.

The method 700 comprises at 701 a process of providing a power electronic substrate comprising a first conductive layer, a second conductive layer and an insulating layer separating the first and second conductive layers; at 702 a process of arranging at least one semiconductor die over the first conductive layer; and at 703 a process of encapsulating the semiconductor die and partially encapsulating the power electronic substrate with a molded body comprising a first side and an opposite second side, such that the second conductive layer is at least partially exposed from the second side of the molded body, wherein the insulating layer protrudes beyond a contour of the first conductive layer and/or beyond a contour of the second conductive layer at lateral sides of the power electronic substrates by a nonzero protrusion, and wherein a ratio of a thickness of the insulating layer to a length of the protrusion is 0.8 or more.

In the following, the semiconductor module, the power electronic substrate and the method for fabricating a semiconductor module are further explained using specific examples.

Example 1 is a semiconductor module, comprising: a power electronic substrate comprising a first conductive layer, a second conductive layer and an insulating layer separating the first and second conductive layers; at least one semiconductor die arranged over the first conductive layer; and a molded body comprising a first side and an opposite second side, the molded body encapsulating the semiconductor die and partially encapsulating the power electronic substrate such that the second conductive layer is at least partially exposed from the second side of the molded body, wherein the insulating layer protrudes beyond a contour of the first conductive layer and/or beyond a contour of the second conductive layer at lateral sides of the power electronic substrate by a nonzero protrusion, and wherein a ratio of a thickness of the insulating layer to a length of the protrusion is 0.8 or more.

Example 2 is the semiconductor module of example 1, wherein the first conductive layer and the second conductive layer have different edge lengths, and wherein the length of the protrusion is calculated with respect to the conductive layer with the larger edge length.

Example 3 is the semiconductor module of example 2, wherein the first conductive layer has a smaller edge length than the second conductive layer.

Example 4 is the semiconductor module of example 3, wherein the edge length of the first conductive layer is at least 0.3 mm smaller than the edge length of the second conductive layer.

Example 5 is the semiconductor module of example 1, wherein the contour of the first conductive layer and the contour of the second conductive layer are congruent.

Example 6 is the semiconductor module of one of the preceding examples, wherein the first conductive layer and/or the second conductive layer comprises a taper at the lateral sides of the power electronic substrate.

Example 7 is the semiconductor module of example 6, wherein the taper has an angle of 30° or more, in particular 45° or more, with respect to a plane which is perpendicular to the first and/or second conductive layer.

Example 8 is the semiconductor module of one of the preceding examples, wherein the second conductive layer is configured to be sintered or soldered to a heatsink.

Example 9 is the semiconductor module of one of the preceding examples, wherein the length of the protrusion is 0.7 mm or less, in particular 0.2 mm or less.

Example 10 is a power electronic substrate configured for use in a semiconductor module, the power electronic substrate comprising: a first conductive layer, a second conductive layer and an insulating layer separating the first and second conductive layers, wherein the insulating layer protrudes beyond a contour of the first conductive layer and/or beyond a contour of the second conductive layer at lateral sides of the power electronic substrate by a nonzero protrusion, and wherein a ratio of a thickness of the insulating layer to a length of the protrusion is 0.8 or more.

Example 11 is the power electronic substrate of example 10, wherein the power electronic substrate is a direct copper bonded substrate, a direct aluminum bonded substrate, or an active metal brazed substrate.

Example 12 is a method for fabricating a semiconductor module, the method comprising: providing a power electronic substrate comprising a first conductive layer, a second conductive layer and an insulating layer separating the first and second conductive layers; arranging at least one semiconductor die over the first conductive layer; and encapsulating the semiconductor die and partially encapsulating the power electronic substrate with a molded body comprising a first side and an opposite second side, such that the second conductive layer is at least partially exposed from the second side of the molded body, wherein the insulating layer protrudes beyond a contour of the first conductive layer and/or beyond a contour of the second conductive layer at lateral sides of the power electronic substrates by a nonzero protrusion, and wherein a ratio of a thickness of the insulating layer to a length of the protrusion is 0.8 or more.

Example 13 is the method of example 12, wherein the second conductive layer is configured to be sintered or soldered to a heatsink.

Example 14 is the method of example 12 or 13, wherein the first conductive layer and/or the second conductive layer has a thickness of 0.25 mm or more.

Example 15 is the method of one of examples 12 to 14, wherein the insulating layer has a thickness of 0.3 mm or more.

Example 16 is the method of one of examples 12 to 15, wherein the ratio is 1.0 or more, in particular 1.2 or more.

Example 17 is an apparatus with means for performing the method according to anyone of examples 12 to 16.

While the disclosure has been illustrated and described with respect to one or more implementations, alterations and/or modifications may be made to the illustrated examples without departing from the spirit and scope of the appended claims. In particular regard to the various functions performed by the above described components or structures (assemblies, devices, circuits, systems, etc.), the terms (including a reference to a “means”) used to describe such components are intended to correspond, unless otherwise indicated, to any component or structure which performs the specified function of the described component (e.g., that is functionally equivalent), even though not structurally equivalent to the disclosed structure which performs the function in the herein illustrated exemplary implementations of the disclosure.

What is claimed is:

1. A semiconductor module, comprising:
a power electronic substrate comprising a first conductive layer, a second conductive layer, and an insulating layer separating the first and second conductive layers;
at least one semiconductor die arranged over the first conductive layer; and
a molded body comprising a first side and an opposite second side, the molded body encapsulating the at least one semiconductor die and partially encapsulating the power electronic substrate such that the second conductive layer is at least partially exposed from the second side of the molded body,
wherein the insulating layer protrudes beyond a contour of the first conductive layer and/or beyond a contour of the second conductive layer at lateral sides of the power electronic substrate by a nonzero protrusion,
wherein a ratio of a thickness of the insulating layer to a length of the protrusion is 0.8 or more.

2. The semiconductor module of claim 1, wherein the first conductive layer and the second conductive layer have different edge lengths, and wherein the length of the protrusion is calculated with respect to the conductive layer with the larger edge length.

3. The semiconductor module of claim 2, wherein the first conductive layer has a smaller edge length than the second conductive layer.

4. The semiconductor module of claim 3, wherein the edge length of the first conductive layer is at least 0.3 mm smaller than the edge length of the second conductive layer.

5. The semiconductor module of claim 1, wherein the contour of the first conductive layer and the contour of the second conductive layer are congruent.

6. The semiconductor module of claim 1, wherein the first conductive layer and/or the second conductive layer comprises a taper at the lateral sides of the power electronic substrate.

7. The semiconductor module of claim 6, wherein the taper has an angle of 30° or more with respect to a plane which is perpendicular to the first and/or second conductive layer.

8. The semiconductor module of claim 7, wherein the angle is 45° or more.

9. The semiconductor module of claim 1, wherein the second conductive layer is configured to be sintered or soldered to a heatsink.

10. The semiconductor module of claim 1, wherein the length of the protrusion is 0.7 mm or less.

11. The semiconductor module of claim 1, wherein the length of the protrusion is 0.2 mm or less.

12. A power electronic substrate configured for use in a semiconductor module, the power electronic substrate comprising:
a first conductive layer;
a second conductive layer; and
an insulating layer separating the first and second conductive layers,
wherein the insulating layer protrudes beyond a contour of the first conductive layer and/or beyond a contour of the second conductive layer at lateral sides of the power electronic substrate by a nonzero protrusion,
wherein a ratio of a thickness of the insulating layer to a length of the protrusion is 0.8 or more.

13. The power electronic substrate of claim 12, wherein the power electronic substrate is a direct copper bonded substrate, a direct aluminum bonded substrate, or an active metal brazed substrate.

14. A method for fabricating a semiconductor module, the method comprising:
providing a power electronic substrate comprising a first conductive layer, a second conductive layer, and an insulating layer separating the first and second conductive layers;
arranging at least one semiconductor die over the first conductive layer; and
encapsulating the at least one semiconductor die and partially encapsulating the power electronic substrate with a molded body comprising a first side and an opposite second side, such that the second conductive layer is at least partially exposed from the second side of the molded body,
wherein the insulating layer protrudes beyond a contour of the first conductive layer and/or beyond a contour of the second conductive layer at lateral sides of the power electronic substrates by a nonzero protrusion,
wherein a ratio of a thickness of the insulating layer to a length of the protrusion is 0.8 or more.

15. The method of claim 14, wherein the second conductive layer is configured to be sintered or soldered to a heatsink.

16. The method of claim 14, wherein the first conductive layer and/or the second conductive layer has a thickness of 0.25 mm or more.

17. The method of claim 14, wherein the insulating layer has a thickness of 0.3 mm or more.

18. The method of claim 14, wherein the ratio is 1.0 or more.

19. The method of claim 14, wherein the ratio is 1.2 or more.
